(19) United States
(12) Patent Application Publication
(10) Pub. No.: US 2009/0017218 A1
(43) Pub. Date: Jan. 15, 2009

(54) Manufacturing Method for Producing Wick Structures of a Vapor Chamber by Using a Powder Thermal Spray Gun

(76) Inventors: Ming-Chen Lin, Taipei Hsien (TW); Kuo-Chang Cheng, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/125,041

(22) Filed: May 21, 2008

(30) Foreign Application Priority Data
Jul. 12, 2007 (TW) 096125442

(51) Int. Cl. C23C 4/08; C23C 16/00

(52) U.S. Cl. 427/456; 118/733

(57) ABSTRACT

Simplifying a manufacturing method for producing wick structures of a vapor chamber includes providing a metal lid, providing a powder thermal spray gun to generate a high temperature blaze to melt a sprayed first powder into a melting surface status, and directly spraying the first powder with the melting surface status on an inner surface of the metal lid to form a first wick structure with a porous status over the inner surface of the metal lid. The manufacturing method further includes putting a cooling system outside the metal lid to keep the metal lid low temperature.

### BACKGROUND OF THE INVENTION

1. Field of the Invention

The present invention provides a manufacturing method for producing wick structures of a vapor chamber, and more particularly, a manufacturing method for producing wick structures of a vapor chamber by using a powder thermal spray gun.

2. Description of the Prior Art

Recently, markets require smaller and leaner electronic products, and heat management becomes more and more important. For example, a hot spot of a center processor unit becomes smaller and smaller, gathering heat on a certain spot, therefore a high thermal conductivity vapor chamber is invented, which evenly distributes heat to a radiator to solve the hot spot problem. When manufacturers produce a wick structure of the vapor chamber, they usually utilize a mandrel to fix an upper lid or lower lid, fill in powder and sinter in a sintering furnace.

In the prior art, sintering is usually used for producing the wick structure of the vapor chamber. Please refer to FIG. 1 and FIG. 2, which illustrate schematic diagrams of a prior art process of manufacturing a sintered wick structure of a vapor chamber. As shown in FIG. 1, first provide a upper metal lid or a lower metal lid, combine a mandrel with the upper metal lid (or the lower metal lid), fill in metal powder between the mandrel and the upper metal lid, and vibrate the metal powder to even the distribution. As shown in FIG. 2, put the mandrel and the upper metal lid mentioned above that is evenly filled with metal powder into a sintering furnace for sintering. After sintering, the metal powder forms a wick structure and covers the inner surface of the upper metal lid. Finally, remove the mandrel to complete the process of sintering the wick structure.

Due to the upper/lower lid of the vapor chamber being too thin, during the process of the sintering, the overly high temperature softens and deforms the upper/lower lid, leads the upper/lower lid to be unsmooth, and produces great production problems. Equipments needed for sintering are expensive, and the steps are complicated, which not only consumes a lot of money and time, but also is not efficient considering production costs.

### SUMMARY OF THE INVENTION

The present invention discloses a manufacturing method for producing wick structures of a vapor chamber by using a powder thermal spray gun, comprising providing a metal lid; providing a powder thermal spray gun for producing a high temperature blaze for melting a sprayed first powder into a melting surface status; putting a cooling system outside the metal lid for keeping the metal lid at low temperature; and directly spraying the first powder with the melting surface status on an inner surface of the metal lid for forming a first wick structure with a porous status over the inner surface of the metal lid. The manufacturing method further comprises providing the powder thermal spray gun for producing a high temperature blaze for melting a sprayed second powder into a melting surface status; and directly spraying the second powder with the melting surface status on an inner surface of the first wick structure for forming a second wick structure with a porous status over the inner surface of the first wick structure.

The present invention discloses a vapor chamber utilizing a powder thermal spay gun for generating wick structures, comprising a metal lid and a first layer wick structure; wherein the first layer wick structure is formed utilizing a powder thermal spray gun for producing high temperature blazes, and spraying a first powder with a melting surface status on an inner surface of the metal lid to form the first wick structure with a porous status over the inner surface of the metal lid. The vapor chamber further comprises a second wick structure; wherein the second layer wick structure is formed utilizing a powder thermal spray gun for generating high temperature blazes, and spraying a second powder with a melting surface status on an inner surface of the first wick structure to form the second wick structure with a porous status over the inner surface of the first wick structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a prior art process of manufacturing a sintered wick structure of a vapor chamber.

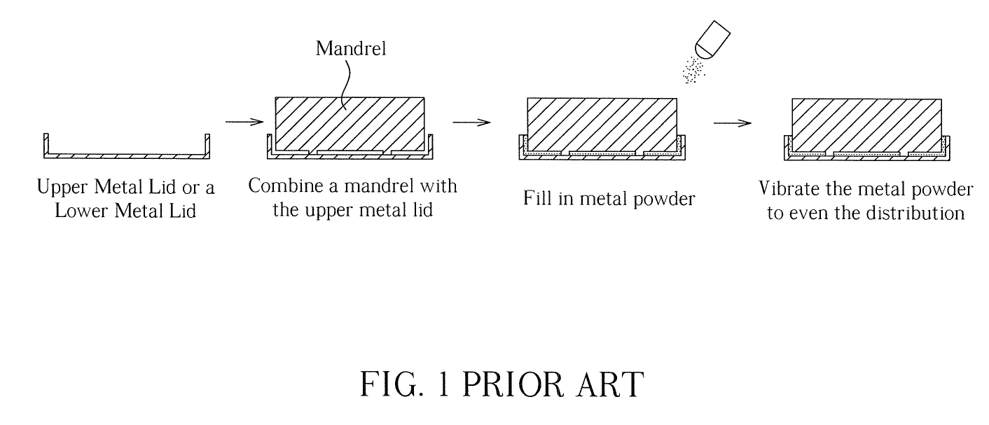

FIG. 2 illustrates a schematic diagram of a prior art process of manufacturing a sintered wick structure of a vapor chamber.

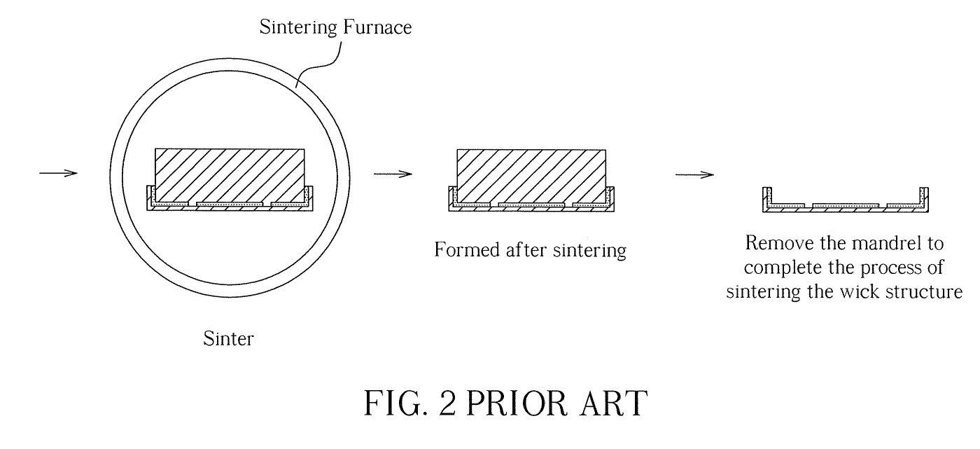

FIG. 3 illustrates a schematic diagram of an embodiment of the present invention of a process of utilizing a powder thermal spray gun for generating a wick structure of a vapor chamber.

FIG. 4 illustrates complete diagrams of wick structures of vapor chambers from FIG. 3.

FIG. 5 illustrates a sectional view of a vapor chamber covered with a wick structure combining a metal upper and a lower metal lid.

FIG. 6 illustrates a diagram of a production method of a first embodiment of the present invention using a powder thermal spray gun to generate a wick structure of a vapor chamber.

FIG. 7 illustrates a schematic diagram of a production procedure of another embodiment of the present invention, using a powder thermal spray gun to generate a wick structure of a vapor chamber.

FIG. 8 illustrates completion diagrams of the two wick structures of the vapor chamber in FIG. 7.

FIG. 9 illustrates a sectional view of an upper metal lid and a lower metal lid of a vapor chamber covered with two layers of wick structures.

FIG. 10 illustrates a diagram of a second embodiment of the present invention, utilizing a powder thermal spray gun to produce a wick structure of a vapor chamber.

FIG. 11 illustrates a schematic diagram for explaining the theory and structure of a powder thermal spray gun.

### DETAILED DESCRIPTION

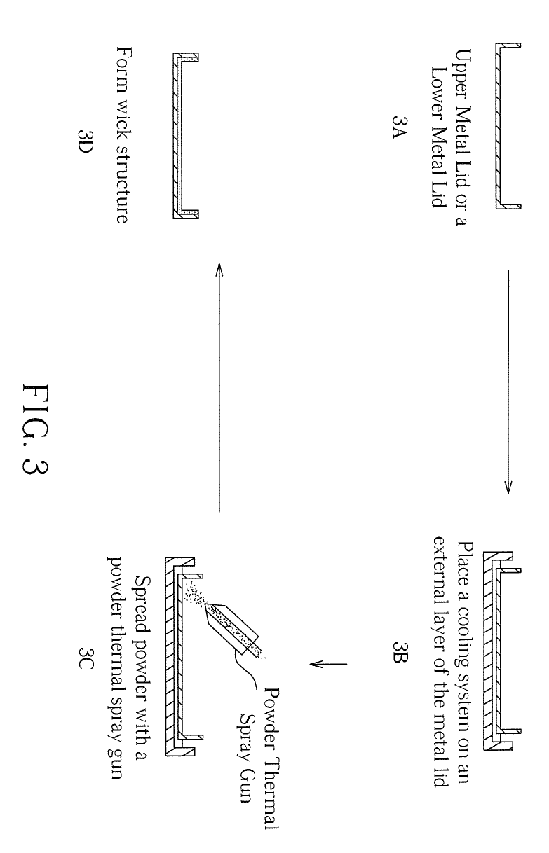

Please refer to FIG. 3, which illustrates a schematic diagram of an embodiment of the present invention of a process of utilizing a powder thermal spray gun for generating a wick structure of a vapor chamber. As shown in FIG. 3, first, provide an upper metal lid or a lower metal lid, and place a cooling system on an external layer of the upper metal lid (or the lower metal lid), to keep the upper metal lid in a cool status. Then, provide a powder thermal spray gun to spray out a first powder with a melting surface status, and directly spray the surface melting first powder on an inner surface of the metal lid. Finally, the first wick structure of the porous status first powder covers the inner surface of the metal lid, and completes the process of producing the wick structure of the vapor chamber.

In the embodiment above, the cooling system is for keeping the upper metal lid in a low temperature status, which may be a cooling tank for storing cooling water, or other cooling equipments, and is not limited. Note that the temperature of the powder thermal spray gun changes with the material of the first powder. For example, a temperature for copper powder should be from 900° C. to 1100° C..

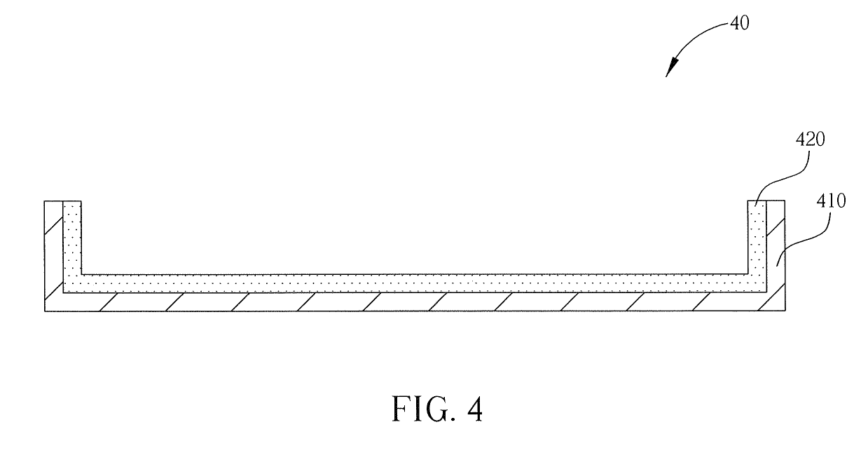

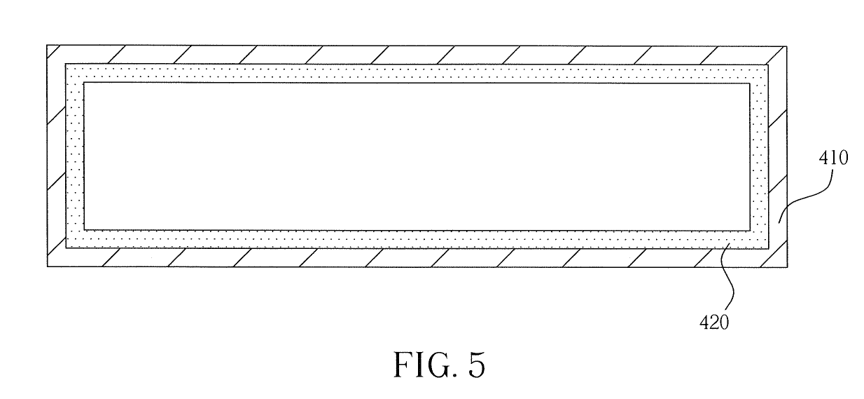

Please refer to FIG. 4 and FIG. 5, which illustrate complete diagrams of wick structures of vapor chambers from FIG. 3, wherein FIG. 4 is a side sectional view of a vapor chamber 40, and FIG. 5 is a sectional view of a vapor chamber covered with a wick structure combining a upper metal lid and a lower metal lid. The vapor chamber 40 comprises an upper metal lid 410, which can be composed of copper, aluminum, or other compound metals. Spray the first powder with a melting surface on an inner surface of the upper metal lid 410, to form a porous status wick structure covered on the inner surface of upper metal lid 410. The first powder can be pure copper powder, aluminum powder or other compound powders; an aperture of the first wick structure is 50 to 200 micrometers (μm), and a thickness is 0.2 to 2.0 millimeters (mm).

Note that the aperture of the first wick structure 420 depends on kernel sizes of the first powder, while the first wick structure formed by the first powder with different kernel sizes or different components can have different apertures, and can be defined according to requirements. For example, a mesh with 50 to 200 meshes can be used for meshing the required kernel size. The thickness of first wick structure 420 is determined by the spray time of the powder thermal spray gun, and can be changed according to requirements.

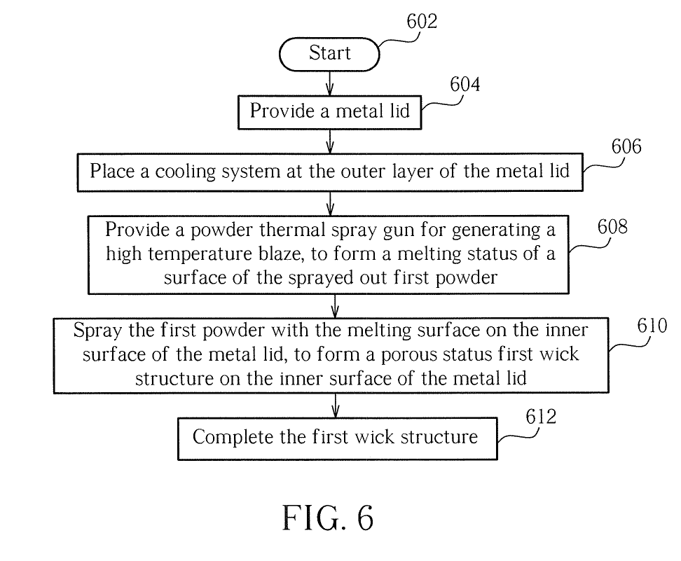

Please refer to FIG. 6, which illustrates a diagram of a production method of a first embodiment of the present invention using a powder thermal spray gun to generate a wick structure of a vapor chamber, which includes the following steps:

Step 602: Start.

Step 604: Provide a metal lid.

Step 606: Place a cooling system at the outer layer of the metal lid, to keep the metal lid in a cool status.

Step 608: Provide a powder thermal spray gun for generating a high temperature blaze, to form a melting status of a surface of the sprayed out first powder.

Step 610: Spray the first powder with the melting surface on the inner surface of the metal lid, to form a porous status first wick structure on the inner surface of the metal lid.

Step 612: Complete the first wick structure.

In order to explain, please also refer to FIG. 3. In step 604, provide a metal lid (such as 3A in FIG. 3). In step 606, place the cooling system at the outer layer of the metal lid (such as 3B in FIG. 3). In steps 608-610, provide a powder thermal spray gun to generate a high temperature blaze, and spray the surface melting first powder on the inner surface of the metal lid (such as 3C in FIG. 3). Finally, complete the first wick structure (such as 3D in FIG. 3).

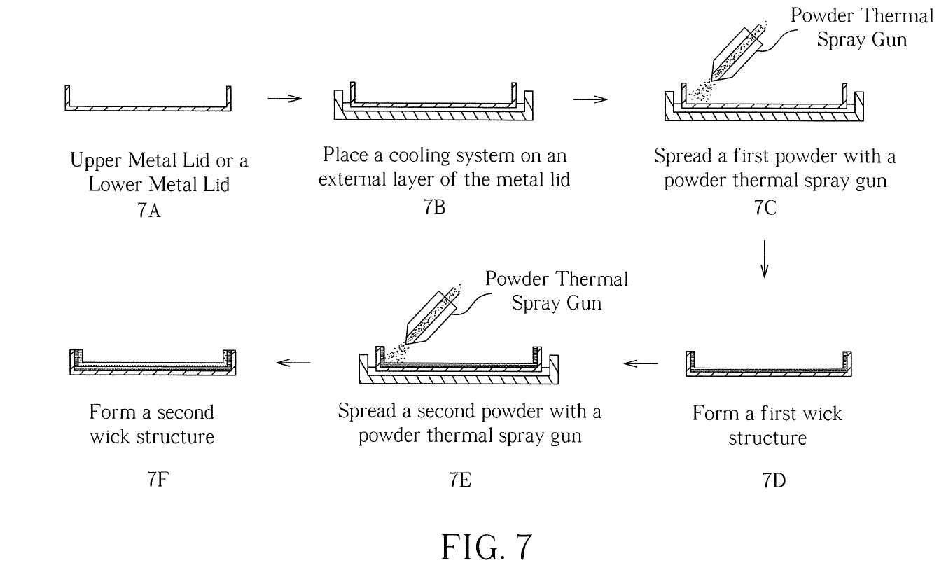

Please refer to FIG. 7, which illustrates a schematic diagram of a production procedure of another embodiment of the present invention, using a powder thermal spray gun to generate a wick structure of a vapor chamber. A production procedure in FIG. 7 resembles the production procedure in FIG. 3, therefore the same parts of the two will not be narrated in detail. The difference between FIG. 7 and FIG. 3 is, FIG. 7 utilizes the powder thermal spray gun, and sprays two different powders on the inner surface of the metal lid, one after another. As shown in FIG. 7, first provide a powder thermal spray gun and melt a surface of a first powder, and spray the first powder with a melting surface on the inner surface of the metal lid, then the porous status first wick structure formed by the first powder covers the inner surface of the inner surface of the metal lid, and completes the first wick structure of the vapor chamber. Then, repeat the steps above, utilize the powder thermal spray gun to melt the surface of a sprayed out second powder, and spray the second powder with a melting surface on the inner surface with the completed first wick structure, so that the porous status second wick structure formed by the second powder covers the inner surface of the first wick structure, so as to complete the production procedure of the second wick structure of the vapor chamber.

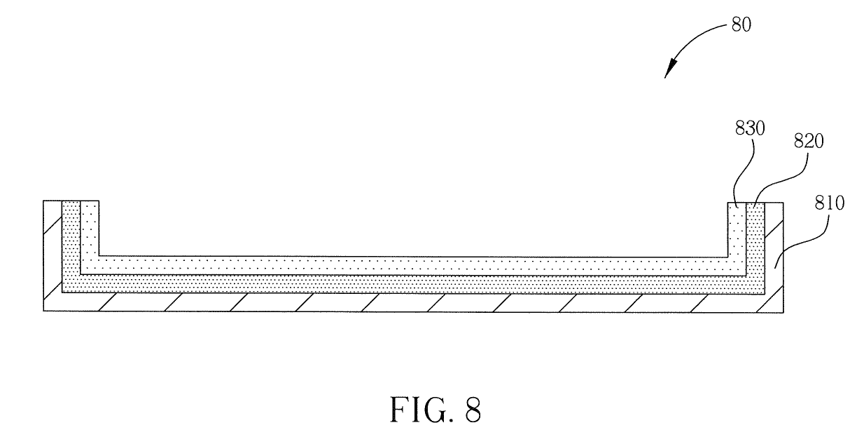

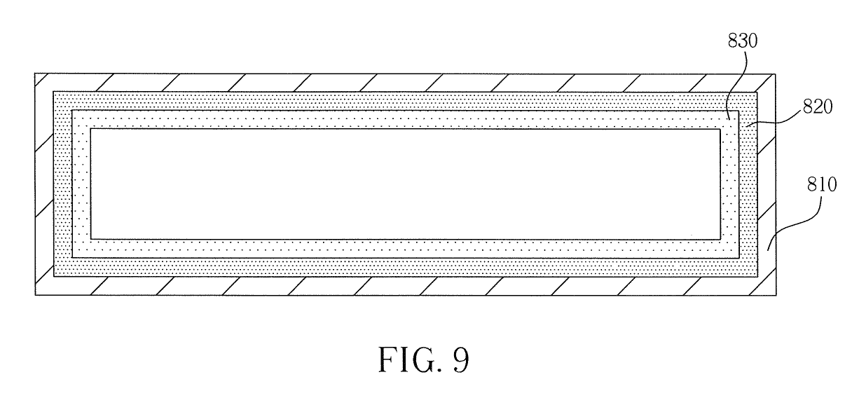

Please refer to FIG. 8 and FIG. 9, which illustrate completion diagrams of the two wick structures of the vapor chamber in FIG. 7. FIG. 8 is a side sectional view of a vapor chamber 80, and FIG. 9 is a sectional view of an upper metal lid and a lower metal lid of a vapor chamber covered with two layers of wick structures. The vapor chamber 80 includes an upper metal lid 810, which can be composed of copper, aluminum or other compound metals. Spray the surface melting first powder on an inner surface of an upper metal lid 810, to form a first wick structure 820 covering the inner surface of the upper metal lid 810. Then, spray the surface melting second powder directly on the inner surface of the first wick structure 820, to form a second wick structure 830 covering the inner surface of the first wick structure. The first powder and the second powder can include pure copper powder, aluminum powder or other compound metal powders. An aperture of the first wick structure 820 is 50 to 200 micrometers, a thickness is 0.2 to 2.0 millimeters; and an aperture of the second wick structure 830 is 50 to 200 micrometers, a thickness is 0.2 to 2.0 millimeters.

In the embodiments above, the first powder and the second powder are sprayed on the inner surface of upper metal lid 810 respectively, to form the first wick structure 820 and the second wick structure 830. Usually kernels of the first powders would be smaller than kernels of the second powder; therefore the aperture of the first wick structure 820 (such as 50 micrometers) would be smaller than the aperture of the second wick structure 830 (such as 200 micrometers). In this way, the first wick structure 820, which is on the lower layer, can have a better permeability, and the second wick structure, which is on the upper layer, can have a better evaporability. The wick structure formed by two different layers of powders can increase heat flux, and enhance efficiencies of the vapor chamber. Note that the apertures of the first wick structure 820 and the second wick structure 830 are not limited by the figures above, and can be defined according to requirements. The thicknesses of the first wick structure 820 and the second wick structure 830 are not limited by the figures above either, and can be changed according to requirements.

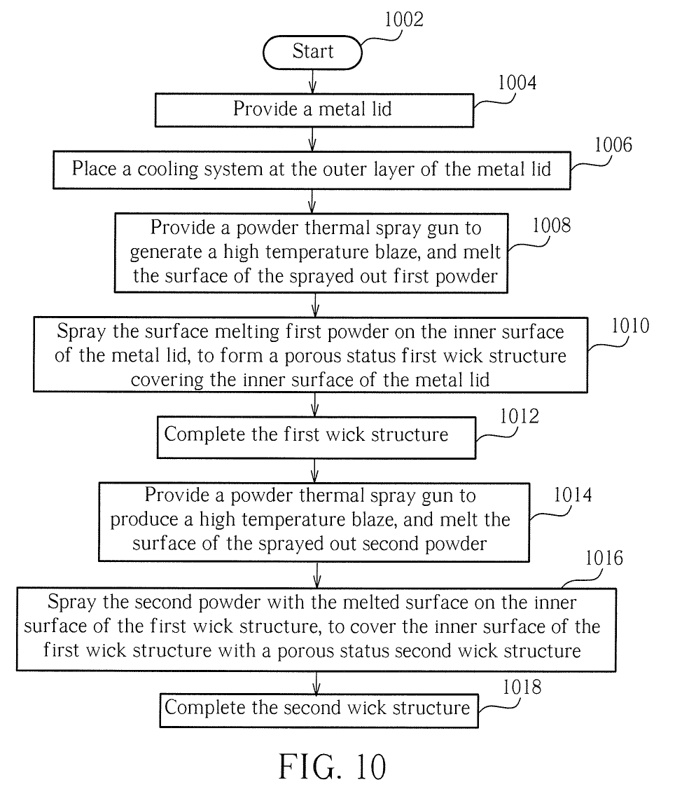

Please refer to FIG. 10, which illustrates a diagram of a second embodiment of the present invention, utilizing a powder thermal spray gun to produce a wick structure of a vapor chamber, including the following steps:

Step 1002: Start. Step 1004: Provide a metal lid.

Step 1006: Place a cooling system at the outer layer of the metal lid, to keep the metal lid cool.

Step 1008: Provide a powder thermal spray gun to generate a high temperature blaze, and melt the surface of the sprayed out first powder.

Step 1010: Spray the surface melting first powder on the inner surface of the metal lid, to form a porous status first wick structure covering the inner surface of the metal lid.

Step 1012: Complete the first wick structure.

Step 1014: Provide a powder thermal spray gun to produce a high temperature blaze, and melt the surface of the sprayed out second powder.

Step 1016: Spray the second powder with the melted surface on the inner surface of the first wick structure, to cover the inner surface of the first wick structure with a porous status second wick structure.

Step 1018: Complete the second wick structure.

In order to explain, please refer to FIG. 7 and compare with FIG. 6. The difference between FIG. 10 and FIG. 6 is that FIG. 10 utilizes the powder thermal spray gun to spray two powders with different kernel sizes, one after another. In steps 1004 to 1006, provide a metal lid (such as 7A in FIG. 7) and place the cooling system at an outer layer of the metal lid (such as 7B in FIG. 7). In steps 1008 to 1010, provide a powder thermal spray gun to generate a high temperature blaze, and directly spray the surface melting first powder on the inner surface of the metal lid (such as 7C in FIG. 7). In this way, complete the first wick structure (as step 1012 in FIG. 10 and 7D in FIG. 7). Then, once again proceed with the high temperature spraying steps, and utilize the powder thermal spray gun to spray the second powder with a melting surface on the inner surface of the first wick structure (as steps 1014 to 1016 and 7E in FIG. 7). It should be noted that the inner surface of the first wick structure is intended to mean the surface of the first wick structure that is towards the center of the vapor chamber, as is shown in the drawings. Finally, complete the second wick structure (as step 1018 in FIG. 10 and 7F in FIG. 7).

Note that procedures in FIG. 6 and FIG. 10 are merely embodiments for explaining the present invention, but not for limiting a range of the present invention, while the steps and details can be modified according to situations such as steps 1014 to 1018 can be substituted by repeating steps 1008 to 1012. Also, above are merely better embodiments of the present invention, all kinds of modifications and designs based on the spirit of the present invention should all be included in the range of the present invention.

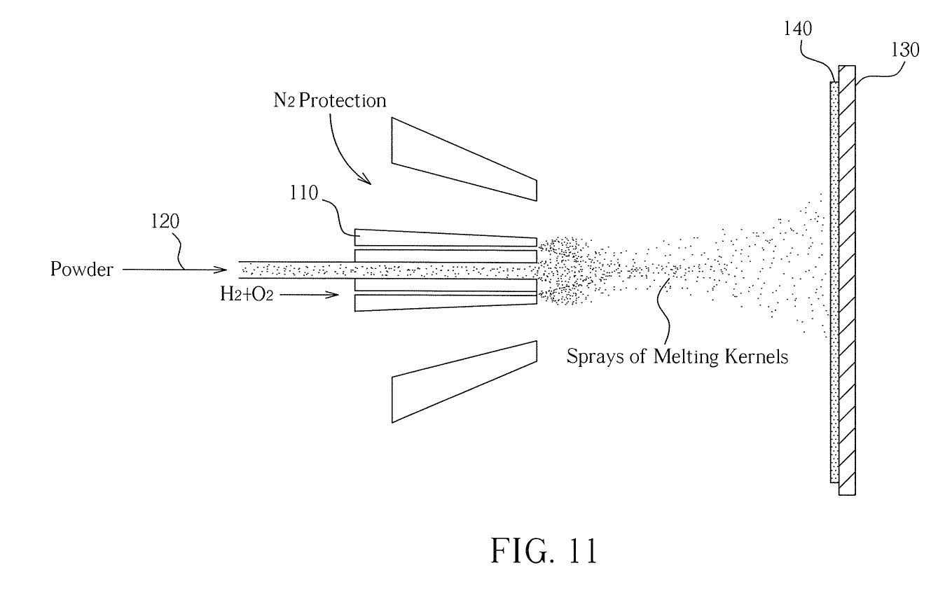

Please refer to FIG. 11, which illustrates a schematic diagram for explaining the theory and a structure of a powder thermal spray gun. A ring-shaped nozzle 110 is designed to produce a high temperature blaze, melt a surface of a sprayed out powder 120, and directly spread the powder 120 having the melted surface on a surface of a metal 130. After the delicate surface melting powder 120 touches colder objects, a porous status spread layer 140 is attached to the surface of the metal 130. That is why this process is called the “cryogenic treatment process”. Without metal 130 going through a high temperature process (such as sintering in a sinter furnace), strength of the object itself can be preserved without being softened, or physically deformed.

The embodiments above are merely for explaining the present invention, but not for limiting a range of the present invention. The mentioned upper metal lid or lower metal lid can be composed of copper, aluminum, or other compound metals, and is not limited to this. The first powder and the second powder can comprise pure copper powder, aluminum powder, or other compound metal powders, and may also be other ingredients to meet requirements. Also, the apertures of the wick structure depend on kernel sizes of the powder, but is not limited to the figures above; and the thicknesses of the first wick structure 820, the second wick structure 830 are not limited to the figures above either, and can be modified according to requirements. Note that in the embodiments above, the number of layers of the wick structure of the vapor chamber is merely for explaining the present invention, but is not limited to one layer or two layers, and can also be expanded to a plurality of layers. The procedures in FIG. 6 and FIG. 10 are merely embodiments of the present invention, but are not limitations of the present invention, while the steps and contents can be changed according to situations.

Known from above, the present invention provides a manufacturing method of utilizing a powder thermal spray gun to produce a wick structure of a vapor chamber. The wick structure manufacturing method of the present invention utilizes the powder thermal spray gun to spread powders on a surface of an upper metal lid or lower metal lid of the vapor chamber, therefore the upper metal lid or the lower metal lid does not need to go through a sintering furnace and be heated, so that the physical strength of the vapor chamber can be maintained without being softened, or unsmoothening the upper/ lower metal lids. Also, the manufacturing method is very simple and convenient, can effectively shorten the manufacturing time and cut costs, and is applicable for mass manufactures of vapor chambers. Through the manufacturing method of the present invention, a first wick structure and a second wick structure can easily be formed, and with wick structures formed by two different powders can enhance heat flux, to enhance efficiencies of the vapor chamber.

Those skilled in the art will readily observe that numerous modifications and alterations of the device and method may be made while retaining the teachings of the invention.

What is claimed is:

1. A manufacturing method for producing wick structures of a vapor chamber by using a powder thermal spray gun, comprising:
providing a metal lid;
providing a powder thermal spray gun for producing a high temperature blaze for melting a sprayed first powder into a melting surface status; and
directly spraying the first powder with the melting surface status on an inner surface of the metal lid for forming a first wick structure with a porous status over the inner surface of the metal lid.

2. The manufacturing method of claim 1, further comprising:
putting a cooling system outside the metal lid for keeping the metal lid at low temperature.

3. The manufacturing method of claim 1, wherein the first power comprises pure copper powder, aluminum powder or other compound metal powders.

4. The manufacturing method of claim 1, wherein an aperture of the first wick structure is 50 to 200 micrometers (μm).

5. The manufacturing method of claim 1, wherein a thickness of the first wick structure is 0.2 to 2.0 millimeters (mm).

6. The manufacturing method of claim 1, further comprising:
providing the powder thermal spray gun for producing a high temperature blaze for melting a sprayed second powder into a melting surface status; and
directly spraying the second powder with the melting surface status on an inner surface of the first wick structure for forming a second wick structure with a porous status over the inner surface of the first wick structure.

7. The manufacturing method of claim 6, wherein the first powder comprises pure copper powder, aluminum powder or other compound metal powders, and the second powder comprises pure copper powder, aluminum powder or other compound metal powders.

8. The manufacturing method of claim 6, wherein kernels of the first powder are smaller than kernels of the second powder.

9. The manufacturing method of claim 6, wherein an aperture of the first wick structure is 50 to 200 micrometers, and an aperture of the second wick structure is 50 to 200 micrometers.

10. The manufacturing method of claim 6, wherein a thickness of the first wick structure is 0.2 to 2.0 millimeters, and a thickness of the second wick structure is 0.2 to 2.0 millimeters.

11. The manufacturing method of claim 6, wherein the metal lid comprises copper, aluminum or other compound metals.

12. The manufacturing method of claim 6, wherein the high temperature blaze generated by the powder thermal spray gun is modified according to materials of the first powder and the second powder.

13. A vapor chamber utilizing a powder thermal spay gun for generating wick structures, comprising:
a metal lid; and
a first layer wick structure;
wherein the first layer wick structure is formed utilizing a powder thermal spray gun for producing high temperature blazes, and spraying a first powder with a melting surface status on an inner surface of the metal lid to form the first wick structure with a porous status over the inner surface of the metal lid.

14. The vapor chamber of claim 13, further comprising:
a second wick structure;
wherein the second layer wick structure is formed utilizing a powder thermal spray gun for generating high temperature blazes, and spraying a second powder with a melting surface status on an inner surface of the first wick structure to form the second wick structure with a porous status over the inner surface of the first wick structure.

15. The vapor chamber of claim 14, wherein the first powder comprises pure copper powder, aluminum powder or other compound metal powders, and the second powder comprises pure copper powder, aluminum powder or other compound metal powders.

16. The vapor chamber of claim 14, wherein kernels of the first powder are smaller than kernels of the second powder.

17. The vapor chamber of claim 14, wherein an aperture of the first wick structure is 50 to 200 micrometers, and an aperture of the second wick structure is 50 to 200 micrometers.

18. The vapor chamber of claim 14, wherein a thickness of the first wick structure is 0.2 to 2.0 millimeters, and a thickness of the second wick structure is 0.2 to 2.0 millimeters.

19. The vapor chamber of claim 14, wherein the metal lid comprises copper, aluminum or other compound metals.
